(19) United States
(12) Patent Application Publication
(10) Pub. No.: US 2009/0320012 A1
(43) Pub. Date: Dec. 24, 2009

(54) SECURE BOOTING FOR UPDATING FIRMWARE OVER THE AIR

(75) Inventors: Chien-Min LEE, Taipei City (TW); Chia-Jung HSU, Taipei City (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 12/132,759

(22) Filed: Jun. 4, 2008

(51) Int. Cl. G06F 9/44; G06F 9/24; H03M 13/00

(52) U.S. Cl. 717/168; 713/2; 714/758; 714/E11.04

(57) ABSTRACT

A firmware updating method for use in a mobile device is provided. The method comprises the following steps. First, during a previous downloading procedure or a previous updating procedure, a flag indicating a current status of the previous downloading procedure or the previous updating procedure, and a signature corresponding to the flag are generated and stored in a non-volatile storage device. Next, the flag and the signature are acquired from the non-volatile storage device when booting subsequent to the previous downloading or updating procedure. Next, integrity of the flag is verified by inspecting the signature. Lastly, the updating procedure is performed to update an original firmware with a new firmware when the integrity of the flag is verified and the flag indicates that the previous updating procedure is undergoing or the previous download procedure is completed.

### BACKGROUND OF THE INVENTION

1. Field of the Invention

The invention relates to updating firmware, and more precisely, to systems and methods for updating firmware on Firmware Over The Air (FOTA) that ensures the integrity of the firmware updating process.

2. Description of the Related Art

Radio communication devices for wireless communication, such as mobile telephones, pagers, personal digital assistants, electronic organizers and so forth, increasingly request and receive embedded software (e.g. firmware) updates from a remote external server, often referred to as Firmware Over The Air (FOTA). FOTA is the technology and process allowing firmware to be updated wirelessly, anywhere and at any time. For FOTA updates, the electronic device is required to operate in a very basic operational mode (i.e. an update mode), in order to proceed with software update. In the basic operational mode (i.e. the update mode), no operating system is launched and only a very basic graphical driver is available. In addition, progress of the updating process is displayed by a progress bar and/or a textual message.

For mobile phones supporting FOTA, security of the mobile phone for protecting image integrity may be broken. Additionally, when there is an unexpected power loss, it may be difficult to recover the update progress. Therefore, solutions addressing the described problem are required.

It is therefore desired to provide firmware updating systems and methods that ensure the integrity of the firmware updating process and provide the user with information regarding the progress of the updating process.

### BRIEF SUMMARY OF THE INVENTION

An embodiment of the invention provides a firmware updating method for use in a mobile device. The method comprises the following steps. First, during a previous downloading procedure or a previous updating procedure, a flag indicating a current status of the previous downloading procedure or the previous updating procedure, and a signature corresponding to the flag are generated and stored in a non-volatile storage device. Next, the flag and the signature are acquired from the non-volatile storage device when booting subsequent to the previous downloading or updating procedure. Next, integrity of the flag is verified by inspecting the signature. Lastly, the updating procedure is performed to update an original firmware with a new firmware when the integrity of the flag is verified and the flag indicates that the previous updating procedure is undergoing or the previous download procedure is completed.

Another embodiment of the invention also provides a firmware updating method for use in a mobile device is further provided. The method comprises the following steps. First, at least one record is found from a flag record block of a non-volatile storage device when booting, wherein each has a flag, a signature and a valid mark. Next, a most recently created record is acquired from the found record or records. Next, integrity of the acquired flag is verified using the signature of the acquired flag. Lastly, an updating procedure is performing to update an original firmware with a new firmware when the integrity of the acquired flag is verified and the acquired flag indicates that a previous updating procedure is undergoing or a previous download procedure is completed.

### BRIEF DESCRIPTION OF THE DRAWINGS

The invention can be more fully understood by reading the subsequent detailed description and examples with reference to the accompanying drawings, wherein:

FIG. 1 is a schematic diagram illustrating an embodiment of a device according to the invention;

FIG. 2 is a diagram illustrating the content within memory space containing a flag record block according to an embodiment of the invention;

FIG. 3 is a diagram illustrating an embodiment of a flag record block according to the invention;

FIG. 4 is a flowchart showing an embodiment of a method for determining operation modes according to the invention;

FIG. 5 is a flowchart showing an embodiment of a process during the normal boot mode shown in FIG. 4 according to the invention;

FIG. 6 is a flowchart showing an embodiment of a process during the update mode shown in FIG. 4 according to the invention;

FIG. 7 is a flowchart showing an embodiment of a process for inserting a flag according to the invention; and

FIG. 8 is a flowchart showing an embodiment of a process for accessing a flag according to the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

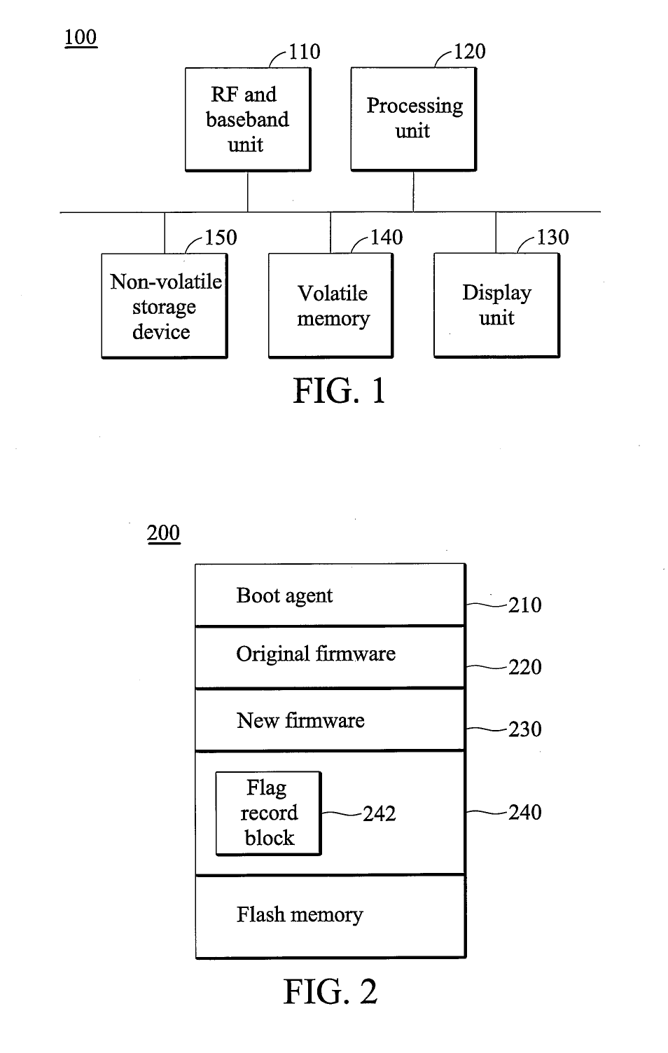

The invention will now be described with reference to FIGS. 1 through 8, which generally relate to systems and methods for updating firmware on Firmware Over The Air (FOTA) that ensures the integrity of the firmware updating process. In the following detailed description, reference is made to the accompanying drawings which form a part hereof, shown by way of illustration of specific embodiments. These embodiments are described in sufficient detail to enable those skilled in the art to practice the invention, and it is to be understood that other embodiments may be utilized and that structural, logical and electrical changes may be made without departing from the spirit and scope of the invention. The following detailed description is, therefore, not to be taken in a limiting sense. It should be understood that many of the elements described and illustrated throughout the specification are functional in nature and may be embodied in one or more physical entities or may take other forms beyond those described or depicted.

FIG. 1 is a schematic diagram illustrating an embodiment of a mobile device 100 according to the invention. The mobile device 100 may be a portable device, such as a mobile phone, a smart phone, or the similar. The device 100 comprises a radio frequency (RF) and baseband unit 110, a processing unit 120, a display unit 130, a volatile memory 140, and a non-volatile storage device 150. The mobile device 100 performs a downloading procedure to download a new firmware version or an updated firmware and performs an updating procedure to update the firmware. The RF and baseband unit 110 receives signals from and transmits signals to the currently associated network. It is to be understood that the processing unit 120 may be integrated into the RF and baseband unit 110. A boot ROM of the RF and baseband unit 110 may store a boot agent (or called boot loader) composed of program code being firstly loaded and executed when the mobile device 100 is turned on (or powered on). The boot agent further determines whether to perform the downloading procedure or the updating procedure. When the mobile device 100 is turned on, the processing unit 120, when executing the boot agent, acquires flag record block from the non-volatile storage device 150 and then determines whether the updating procedure is required to be performed according to the content of the acquired flag record block. The flag record block records at least one record containing a current status of the downloading procedure or the updating procedure (may be indicated by a flag), a signature and a valid mark. The signature is utilized to verify the status integrity. The valid mark is generated and stored after the current status and the signature is successfully written in the non-volatile storage device 150. If the status of the acquired flag block indicates that the updating procedure is not yet finished, the processing unit 120 determines to perform the updating procedure. Otherwise, a normal boot procedure is executed.

The volatile memory 140, such as a dynamic random access memory (DRAM), static random access memory (SRAM), or others, may store the computer program to be accessed by the processing unit 120.

The processing unit 120, when executing program code, performs methods for updating firmware for use in a mobile device. Several embodiments of methods for updating firmware are provided.

FIG. 2 is a diagram illustrating the content within memory space containing a flag record block according to an embodiment of the invention. The memory space 200 may comprise a boot ROM of the RF and baseband unit 110 storing a boot agent 210 being the first executed module or program when the mobile device is powered on or reset. The memory space 200 may comprise a flash memory of the non-volatile storage device 150 for storing original firmware 220, new firmware 230 and a flag record block 242. The original firmware 220 comprises the operating system, drivers and related applications for initiating the system. The original firmware 220 is to be updated with the new firmware 230 comprising new versions of operating system, drivers and related applications. The flag record block 242 stores information indicating current/historical progresses of the downloading procedure and/or the updating procedure.

A flag value of the flag record block 242 may be, for example, but is not limited to, “Under_download” for indicating that the downloading procedure is not finished yet, “Download_done” for indicating that the downloading procedure is finished, “Under_update” for indicating that the updating procedure is not finished yet, and “Update_done” for indicating that the update procedure is finished.

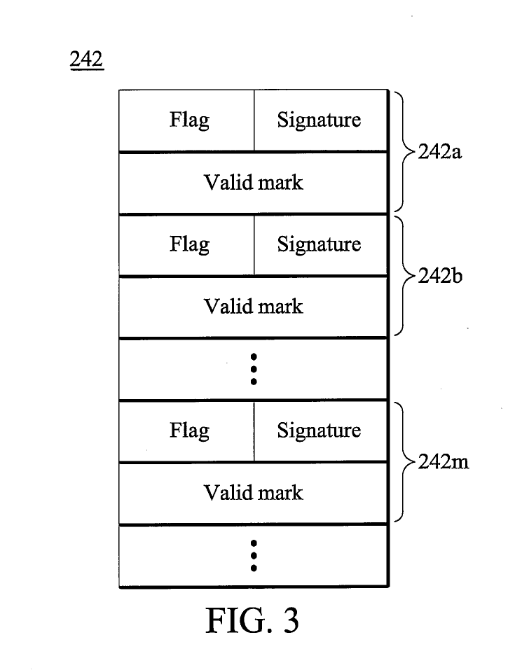

FIG. 3 shows an embodiment of a flag record block according to the invention. Continuous space of the flash memory is allocated for the flag record block 242. The flag record block 242 may store multiple records with fixed lengths in sequence, for example 242a, 242b to 242m, to increase search efficiency. As shown in FIG. 3, the data structure of each record (e.g. 242a, 242b or 242m) contains a flag value, a signature and a valid mark in which the flag value is used for indicating a progress or status of the downloading or updating procedure. The flag record block 242 may keep only one record storing the most recent flag or store a certain number of records storing historical flags. The valid mark composed of a particular pattern recognized by the mobile device 100 is utilized as a boundary between two adjacent pairs of flag and signature or between a record and unused space of the flag record block 242. After a pair of flag and signature has been successfully recorded, the valid mark is adjacently written thereto. The flag is used to determine a progress of the downloading procedure or the updating procedure and further used to determine whether downloading or updating is required and designated with a state transition. The signature may be a cyclic redundancy check (CRC) code of the flag. The signature may be an encryption of the flag using a specific key (e.g. a unique number for the mobile device 100). The signature may be a hash value of the flag using a predetermined hash function. A hash value of the flag may be firstly acquired using a predetermined hash function, and the hash value is encrypted using a specific key to generate the signature.

Referring to FIG. 2, before booting up the system, the processing unit 120 executing the boot agent 210 accesses the most recently updated flag from the dedicated block 242 and inspects that whether any valid flag exists. It is to be understood that a valid flag is a flag has been successfully verified by inspecting a corresponding signature. If no valid flag exists, the system may fail to boot due to a possible intrusion. If at least one valid flag exists, the last recorded flag will be retrieved.

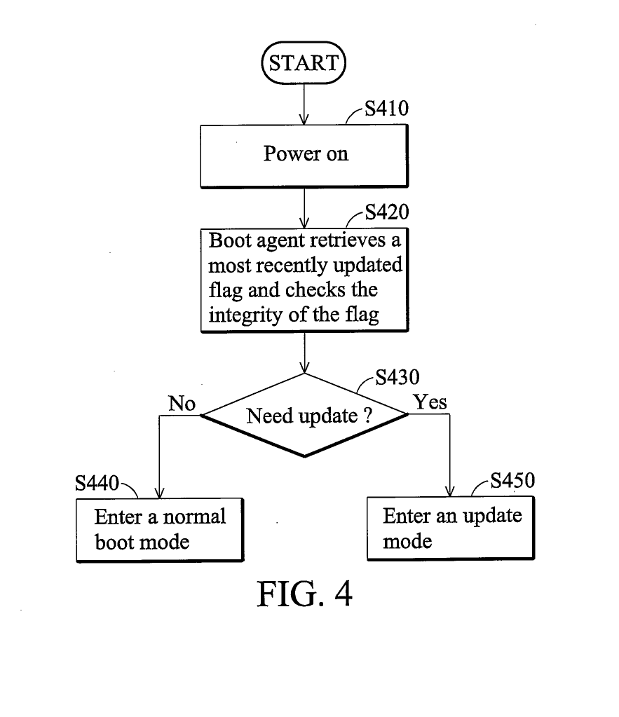

FIG. 4 is a flowchart showing an embodiment of a method for determining operation modes according to the invention. In step S410, the mobile device 100 is powered on or reset. Accordingly, the boot agent is loaded and executed by the processing unit 120. In step S420, the boot agent retrieves a most recently updated flag and checks the integrity of the flag. The flag integrity may be determined by checking the signature corresponding to the flag. For an example as the signature being a CRC code, a CRC code of the retrieved flag is calculated. The retrieved flag is valid when the calculated CRC code is the same as the signature, otherwise, the flag is not intact. For another example as the signature being an encrypting value of a flag, the encrypting value is decrypted using a specific key. The retrieved flag is valid when the decrypted value is the same as the flag value, otherwise, the flag is not intact. For still another example as the signature being an encrypting value of a hash value of a flag, the encrypting value is decrypted using a specific key and the flag value is hashed using a hash function. The retrieved flag is valid when the encrypted value is the same as the hash value, otherwise, the flag is not intact.

Then, in step S430, the boot agent determines whether an updating procedure is needed by inspecting the value of the flag. If the flag is “Under_update” (i.e. firmware update is not finished) or “Download_done” (i.e. completes firmware download), an update mode for firmware updating is entered (step S450). If the flag is “Under_download” (i.e. download is not finished) or “Update_done” (i.e. no further update is needed), a normal boot mode for initiating the system is entered (step S440).

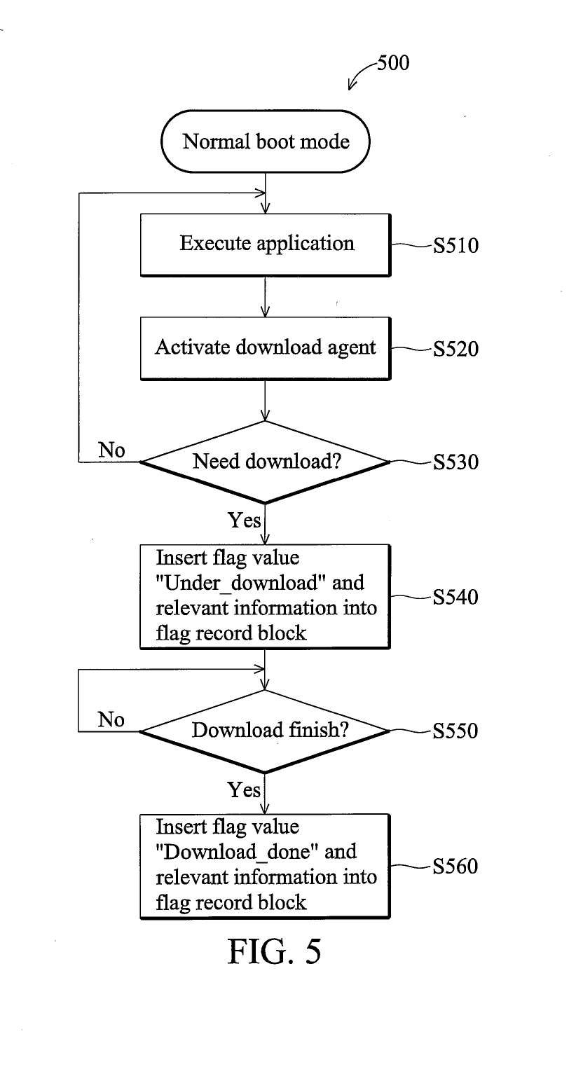

FIG. 5 is a flowchart showing an embodiment of a process during the normal boot mode shown in FIG. 4 according to the invention. When the mobile device is operated in the normal boot mode, in step S510, the original firmware that comprises the OS, related drivers and applications is loaded and executed by the processing unit 120. After completely running the applications, in step S520, a download agent capable of interaction with a remote external server for downloading new firmware is activated (i.e. loaded and executed) via an executed application. In step S530, the activated download agent determines whether any download is needed. If no download is needed, the process goes to step S510. If so (Yes in step S530), in step S540, a flag with a value “Under_download” indicating that the download is undergoing is provided. A signature corresponding to the inserted flag and a specific valid mark are also provided. A record containing the provided flag, signature and valid mark is inserted to the flag record block 520, following the last record, as shown in FIG. 3. Then, the download agent communicates with a remote external server to perform a download procedure to download a new firmware version. In step S550, it is determined whether the download is finished. If so, in step S560, a flag with a value “Download_done” indicating that the download is finished is provided. A record containing the provided flag, a corresponding signature and the valid mark is inserted to the flag record block 520, following the last record, as shown in FIG. 3. If not (No in step S550), after a predetermined time period the process goes to step S550 to determine whether the download is finished again.

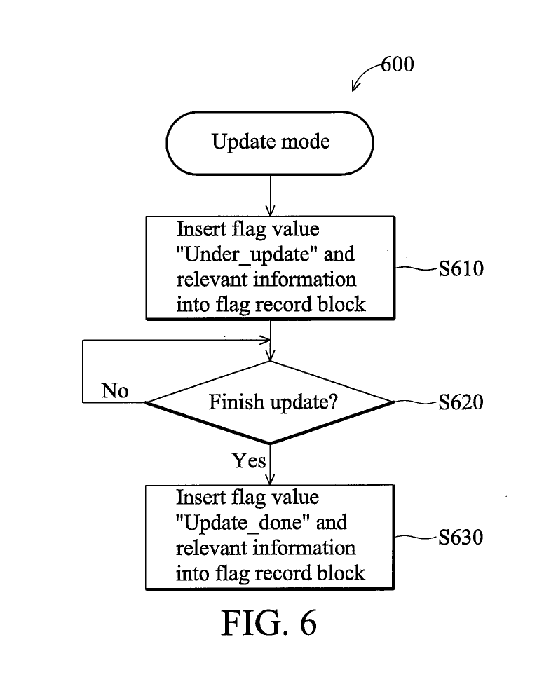

FIG. 6 is a flowchart showing an embodiment of a process during the update mode shown in FIG. 4 according to the invention. When the mobile device is operated in the update mode, in step S610, a flag with a value “Under_update” indicating that the update is undergoing is provided. A record containing the provided flag, a corresponding signature and the valid mark is inserted to the flag record block 520, following the last record, as shown in FIG. 3. And then, the original firmware 220 is replaced with the new firmware 230. In step S620, the executed boot agent checks whether the update is finished. If so, in step S630, a flag with a value “Update_done” indicating that the update is finished is provided. A record containing the provided flag, a corresponding signature and the valid mark is inserted to the flag record block 520, following the last record, as shown in FIG. 3. If not (No in step S620), after a predetermined time period the process goes to step S620 to determine whether the update is finished again.

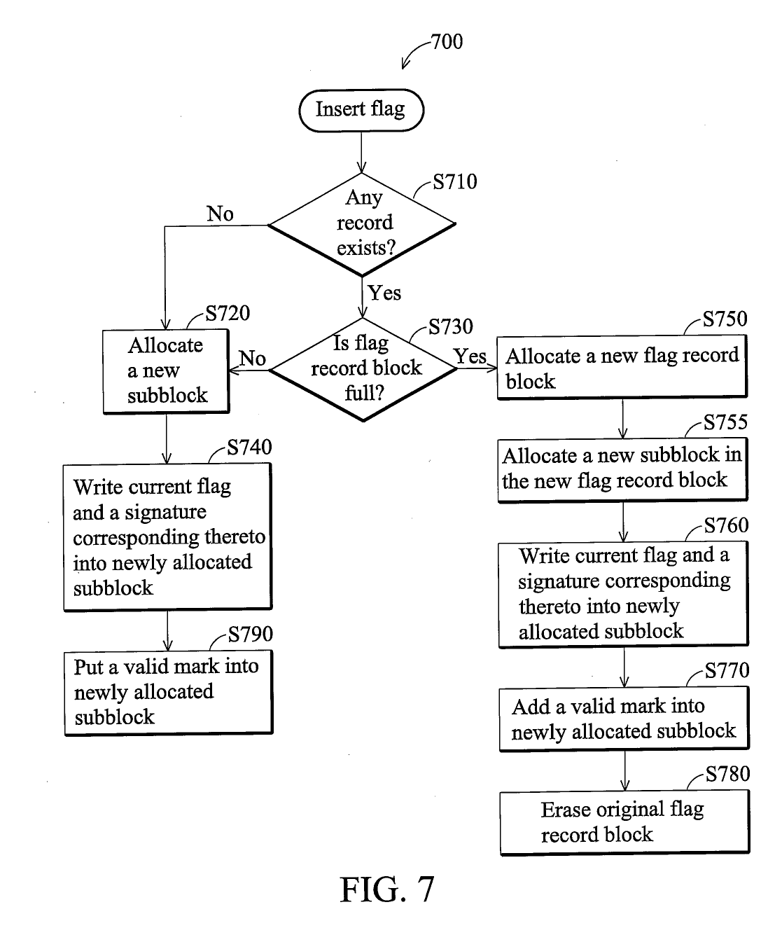

FIG. 7 is a flowchart showing an embodiment of a process for inserting a flag according to the invention. When inserting a flag, in step S710, it is first checked whether any record exists. If not, in step S720, it may be the first time for generating a record or the first record may be inoperative, so a new subblock is allocated in the flag record block 242. After allocating the new subblock, the method goes to step S740. If so (Yes in step S710), in step S730, it is then determined whether the flag record block 242 is full. If the flag record block 242 is not full, in step S720, a new subblock is allocated following the last subblock of the flag record block 242, in step S740, the current flag and a signature corresponding thereto are written into the newly allocated subblock. Then, in step S790, after the current flag and the corresponding signature is successfully written, a valid mark is also put into the newly allocated subblock following the current flag and the corresponding signature. It is to be understood that the current flag, corresponding signature and valid mark compose a record and exemplary data structure for the record may refer to FIG. 3.

If the flag record block is full, the method processes steps S750-S780. In step S750, a new flag record block is allocated. In step S755, a new subblock is allocated in the new flag record block. In step S760, the current flag and a signature corresponding thereto are written into the newly allocated subblock. Then, in step S770, after the current flag and the corresponding signature is successfully written, a valid mark is put into the newly allocated subblock following the current flag and the corresponding signature. In step S780, the original flag record block 242 is erased.

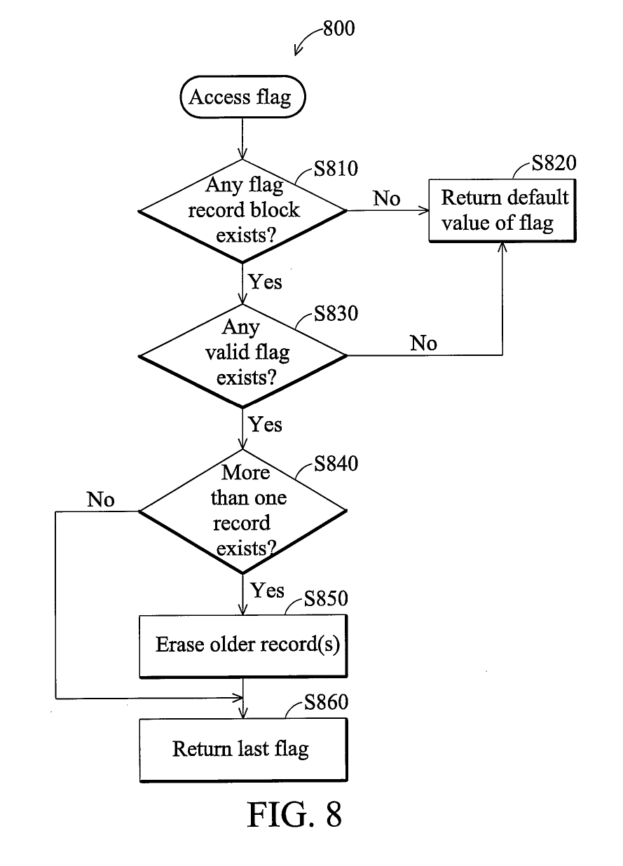

FIG. 8 is a flowchart showing an embodiment of a process for accessing a flag according to the invention. In step S810, it is first checked whether any flag record block exist. If not, in step S820, no flag record block is allocated or a flag record block may be inoperative, so a default value of the flag is returned. The default value of the flag may be, for example, but is not limited to, a flag “Initial” indicating that a new flag record block is required be generated. If so (Yes in step S810), in step S830, it is then determined whether any valid flag exists. If no valid flag exists, step S820 is performed to return the default value of the flag (e.g. the flag “Initial”). If any valid flag exists (Yes in step S830), in step S840, it is then determined whether more than one record of the flag record block exists. If only one record exists, in step S860, the flag of the detected record is returned. If two or more records exist, steps S850-S860 are performed. In step S850, the record(s) older than the last record is(are) erased. It is to be understood that when the records are adjacently stored according to the established times of the records from the earliest to the latest. Records established earlier than the last record are erased and the last record is moved to the beginning of the flag record block. In step S860, the last flag is returned.

By referring to flags of a flag record block during booting, wherein each flag indicates the progress of the downloading procedure or the updating procedure, especially for updating firmware on FOTA, an interrupted downloading procedure or updating procedure caused by an unexpected power loss, traffic jam in wireless network, or others can be properly resumed.

The described embodiments for updating firmware using FOTA, or certain aspects or portions thereof, may be practiced in logic circuits, or may take the form of program codes (i.e., instructions) embodied in tangible media, such as floppy diskettes, CD-ROMS, hard drives, or any other machine-readable storage device, wherein, when the program codes are loaded into and executed by a machine, such as a smart phone, a mobile phone, or similar, the machine becomes an apparatus for practicing the invention. The disclosed methods may also be embodied in the form of program codes transmitted over some transmission medium, such as electrical wiring or cabling, through fiber optics, or via any other form of transmission, wherein, when the program codes are received and loaded into and executed by a machine, the machine becomes an apparatus for practicing the invention. When implemented on a general-purpose processor (e.g. 110 of FIG. 1), the program codes combine with the processor to provide a unique apparatus that operate analogously to specific logic circuits.

While the invention has been described by way of example and in terms of preferred embodiment, it is to be understood that the invention is not limited thereto. To the contrary, it is intended to cover various modifications and similar arrangements (as would be apparent to the skilled in the art). Therefore, the scope of the appended claims should be accorded to the broadest interpretation so as to encompass all such modifications and similar arrangements.

What is claimed is:

1. A firmware updating method for use in a mobile device, comprising:
during a previous downloading procedure or a previous updating procedure, generating and storing a flag indicating a current status of the previous downloading procedure or the previous updating procedure, and a signature corresponding to the flag in a non-volatile storage device;
acquiring the flag and the signature from the non-volatile storage device when booting subsequent to the previous downloading or updating procedure;
verifying an integrity of the flag by inspecting the signature; and
performing the updating procedure to update an original firmware with a new firmware when the integrity of the flag is verified and the flag indicates that the previous updating procedure is undergoing or the previous download procedure is completed.

2. The method of claim 1, further comprising:
performing a normal booting procedure for initiating system when the integrity of the flag is not verified or the flag does not indicate that updating procedure is undergoing or the previous download procedure is completed.

3. The method of claim 1, wherein the original firmware is loaded and executed during the normal booting procedure.

4. The method of claim 3, wherein the flag indicating that the previous downloading procedure is undergoing is generated and stored before downloading the new firmware.

5. The method of claim 3, wherein the flag indicating that the previous downloading procedure is completed is generated and stored after the new firmware is completely downloaded.

6. The method of claim 3, wherein the flag indicating that the previous updating procedure is undergoing is generated and stored before updating the original firmware with the new firmware.

7. The method of claim 3, wherein the flag indicating that the previous updating procedure is completed is generated and stored after completely updating the original firmware with the new firmware.

8. The method of claim 1, wherein the generating and storing step further comprises:
generating a valid mark following the flag and the signature.

9. The method of claim 1, wherein a flag record block is allocated in the non-volatile storage device and the generating and storing step further comprises:
determining whether the flag record block is full;
if the flag block is full, allocating a new flag record block in the non-volatile storage device;
writing the flag and the signature in the newly allocated flag record block;
writing a valid mark following the flag and the signature; and
erasing the full flag record block.

10. The method of claim 9, further comprising:
if the flag record block is not full, writing the flag, the signature and a valid mark in the flag record block following the last valid mark.

11. The method of claim 8, wherein the signature is a cyclic redundancy check (CRC) code of the flag.

12. The method of claim 8, wherein the signature is an encryption of the flag using a specific key.

13. The method of claim 8, wherein the signature is generated by hashing the flag using a hash function and encrypting the hash value using a specific key.

14. A firmware updating method for use in a mobile device, comprising:
finding at least one record from a flag record block of a non-volatile storage device when booting, wherein each has a flag, a signature and a valid mark;
acquiring a most recently created record from the found record or records;
verifying an integrity of the acquired flag using the signature of the acquired flag; and
performing a updating procedure to update an original firmware with a new firmware when the integrity of the acquired flag is verified and the acquired flag indicates that a previous updating procedure is undergoing or a previous download procedure is completed.

15. The method of claim 14, wherein the valid mark is utilized as a boundary between two adjacent pairs of flag and signature or between a record and unused space of the flag record block.

16. The method of claim 14, wherein when more than one record is found, the found records are adjacently stored according to the established times thereof from the earliest to the latest, and the acquired record is the last record of the flag record block.

17. The method of claim 16, wherein the acquiring step further comprises:
erasing records earlier than the acquired record; and
moving the acquired record to the beginning of the flag record block.
